(19) United States
(12) Patent Application Publication
(10) Pub. No.: US 2005/0135167 A1
(43) Pub. Date: Jun. 23, 2005

(54) Memory access circuit for adjusting delay of internal clock signal used for memory control

(75) Inventor: Takashi Manabe, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC PLASMA DISPLAY CORPORATION

(21) Appl. No.: 10/950,471

(22) Filed: Sep. 28, 2004

(30) Foreign Application Priority Data
Oct. 16, 2003 (JP) 355771/2003

(51) Int. Cl. G11C 7/00

(52) U.S. Cl. 365/201

(57) ABSTRACT

It is to form a memory access circuit comprising a memory, a clock generator for generating a reference clock signal, and a clock delay adjusting circuit for delaying the reference clock signal to create a delay clock signal. The clock delay adjusting circuit is a circuit for generating a plurality of delay clock signals of various delay value. The memory access circuit further comprises a test data generator for generating test data and a memory access test controller for supplying a memory writing test start signal in reply to the external synchronizing signal. The test data generator generates the test data in reply to the memory writing test start signal, writes the test data into the memory in synchronization with the reference clock, and supplies the write data corresponding to the test data in synchronization with the reference clock, and the memory access test controller reads the test data from the memory in synchronization with the delay clock signal, compares the read test data with the write data, and adjusts the memory access timing according to as a result of the comparison.

### BACKGROUND OF THE INVENTION

1. Field of the Invention

The present invention relates to a semiconductor integrated circuit, and more particularly to a memory access circuit.

2. Description of the Related Art

A memory such as a DDR (Double Data Rate) SDRAM operates in synchronization with clock pulses supplied thereto. For example, data having predetermined number of bits is supplied to a data input terminal of the DDR SDRAM when the data is written into the DDR SDRAM. Together with the data input, a writing head address is supplied to its address input terminal and a clock signal is supplied to the DDR SDRAM. The DDR SDRAM writes one bit of the data into the corresponding head address upon receipt of an initial clock signal and sequentially writes each of the other bits of the data into each address following the head address each time of receiving the succeeding clock signal.

When a semiconductor integrated circuit for receiving and transmitting data from and to such a memory supplies write data and its writing address to the memory, it also supplies the clock signal there. When it also supplies read data and its reading address to the memory, it supplies the clock signal. Writing/reading of the data is performed in synchronization with the clock.

In a circuit having a semiconductor integrated circuit and a memory connected thereto, a distance between data input and output terminals of a data supplying unit and a memory is different from a distance between clock signal input and output terminals of a clock signal supplying unit and the memory. Similarly, a distance between address input and output terminals of an address supplying unit and the memory is generally different from the distance between the clock signal input and output terminals of the clock signal supplying unit and the memory. There occurs a time deviation in signals transmitting between the both owing to a wiring delay therebetween. In order to solve the time deviation, a semiconductor integrated circuit has to be designed to adjust a timing of supplying a clock signal to a memory in order to transfer data assuredly.

In order to adjust the timing of supplying a clock signal to a memory to transfer data assuredly, a semiconductor integrated circuit is provided with a memory access circuit of adjusting a delay of an internal clock, hence to supply it to a memory.

The current prevailing DDR (Double Data Rate) SDRAM operates at 166 MHz. Its data cycle is very short, that is, 3 ns. In this SDRAM, delay time may vary because of various factors. The degree of fluctuation in the delay time is about 2 ns. It is, however, very important for the SDRAM operating at a high speed to take the effect of this fluctuation into consideration. The factor of changing a delay includes, for example, difference in the processes by the SDRAM and the memory access circuit, scattering of electric constant of a board connecting between the SDRAM and the memory access circuit, a change in an operational environment temperature, and a change in the power voltage, etc. Since a change in delay occurs because of these factors, it is difficult to estimate the details of a delay time taken to read out data from an external memory at a time of designing a memory access circuit. When a reading delay from a memory and a wiring delay change from the values at a time of designing LSI, there is a possibility of causing a malfunction or a lack of operation margin of the LSI having a memory access circuit. Then, the structure of a circuit that can switch a clock delay for taking reading data from the SDRAM is being used.

Hitherto, a technique for testing memory access while changing a clock delay is well known (for example, refer to Patent Document 1). In this technique, a clock delay is judged in order to correctly transfer data and general memory access is performed with the judged clock delay. This circuit adjusts a memory access timing at a time of power-on, reset, receiving a test signal outwards, or at intervals of predetermined time.

In the memory access timing adjustment according to the technique described in Japanese Patent Kokai No. P2000-235517A, memory access timing is adjusted at a time of power-on or reset. When the optimum delay of a clock changes because of some factor during an operation of the memory access circuit, there is a possibility of causing malfunction. For example, the value of a delay may change according to a change in the surrounding temperature or a change in the power voltage and the value may be deviated from the intended delay value. Accordingly, the operation assured temperature may be restricted or the operation assured voltage may be narrowed. In particular, when using a high speed memory, a change in the delay value may restrict the assured operation extremely. For example, when driving a memory at 333 MHz, one cycle includes only 3 nsec, and a change in the delay value according to a change in the temperature is large, that is, 2 ns, which presses the operation margin extremely. In the conventional technique, memory access timing has been adjusted at a time of receiving a test signal from the outward or at intervals of predetermined time. Desired is a memory access timing adjusting circuit that does not have to interrupt the original processing even during the adjustment period.

### SUMMARY OF THE INVENTION

An object of the invention is to provide a memory access circuit for adjusting a memory access timing without restricting the performance during the data processing operation.

Another object of the invention is to provide a memory access circuit for determining the optimum memory access timing that can follow a change of clock delay according to the environmental change in temperature, power voltage, and the like.

In accordance with one aspect of the present invention, there is provided a memory access circuit comprising a memory, a clock generator for generating a reference clock signal, and a clock delay adjusting circuit for delaying the reference clock signal to create a delay clock signal. Here, the clock delay adjusting circuit is to create a plurality of delay clock signals of various delay values. The memory access circuit further comprises a test data generator for generating test data and a memory access test controller for supplying a memory test start signal in reply to an external synchronizing signal.

The test data generator generates the test data in reply to the memory test start signal, writes the test data into the memory in synchronization with the reference clock, and supplies the write data corresponding to the test data in synchronization with the reference clock, and the memory access test controller reads the test data from the memory in synchronization with the delay clock signal, compares the read test data with the write data, and adjusts a memory access timing of the memory access circuit according to a result of the comparison.

The memory access circuit further comprises a data reading circuit for reading the test data written into the memory in synchronization with each of the delay clock signals and a comparator for comparing the read test data with the write data, wherein the data reading circuit reads the test data in synchronization with each of the delay clock signals, the comparator compares each of the read test data with the write data and notifies the memory access test controller of the comparison result, and the memory access test controller adjusts the memory access timing of the memory access circuit according to the comparison result.

It is preferable that the memory access circuit further comprises a data delay adjusting circuit. The test data generator generates the test data in reply to the memory test start signal and supplies the test data to the data delay adjusting circuit in synchronization with the reference clock. The data delay adjusting circuit constitutes the memory access circuit which adjusts a writing timing into the memory based on the comparison between the test data and the read test data.

In the memory access circuit, the memory access test controller adjusts the memory access timing of the memory access circuit between a front porch of the external synchronizing signal and a back porch of the external synchronizing signal.

In the memory access circuit, the external synchronizing signal includes a first signal and a second signal and has a blanking period including no data signal between the first signal and the second signal, and the memory access test controller adjusts the memory access timing of the memory access circuit during the blanking period.

As mentioned above, by adjusting the memory access timing using the external signal having the blanking period, the period during which a memory access is not performed can be effectively used and a stable output can be expected, in particular, in the case of the data processing requiring real time processing.

In the memory access circuit, its memory access timing is adjusted by using a vertical synchronizing signal for the external synchronizing signal. Also in the memory access circuit, its memory access timing is adjusted by using a horizontal synchronizing signal as the external synchronizing signal.

In order to solve the above problem, the memory access circuit may be configured as follows. It is preferable that the memory access circuit comprises a memory for specifying an input timing of data according to an input data-strobe signal (input DQS) and specifying an output timing of data according to an output data-strobe signal (output DQS). Further, it comprises a first delay adjusting circuit for delaying the output data-strobe signal to create a delay output data-strobe signal. The first delay adjusting circuit creates a plurality of delay output data-strobe signals (output DQS) of various delay values. Further the memory access circuit comprises a test data generator for generating test data, a memory access controller for creating address data and the input data-strobe signal (input DQS), and a memory access test controller for supplying a memory test start signal in reply to the external synchronizing signal.

The test data generator generates the test data in reply to the memory test start signal and enters the same data into the memory, the memory access controller enters the input data-strobe signal (input DQS) into the memory in synchronization with the test data, and the memory access test controller reads the test data from the memory in synchronization with the delay output data-strobe signal, compares the test data generated in the test data generator with the read data, and adjusts a memory access timing according to a result of the comparison.

In the memory access circuit, the memory access timing is adjusted by comparing the read test data with the test data generated by the test data generator according to the delay output data-strobe signals of various delay values generated by the first delay adjusting circuit and by selecting the delay output data-strobe signal in case where the comparison results in agreement.

It is preferable that the memory access circuit further comprises a second delay adjusting circuit for delaying the input data-strobe signal (input DQS) to create a delay input data-strobe signal. The second delay adjusting circuit creates a plurality of delay input data-strobe signals of various delay values and enters the same signals into the memory. The memory access test controller reads the test data from the memory in synchronization with the delay output data-strobe, compares the test data generated by the test data generator with the read test data, and adjusts the memory access timing according to a result of the comparison.

In the memory access circuit, the memory access timing is adjusted by comparing the read test data with the test data generated by the test data generator according to each combination of the delay output data-strobe signals of various delay values generated by the first delay adjusting circuit and the delay input data-strobe signals of various delay values generated by the second delay adjusting circuit and by selecting the combination of the delay output data-strobe signal and the delay input data-strobe signal in case where the comparison results in agreement.

In the memory access circuit, a memory access timing to the actual data (the data other than the test data) is established at the timing adjusted in the above memory access timing adjustment.

This invention can be applied to a display having the above-mentioned memory access circuit and a display unit for displaying an external display signal.

In this case, it is preferable that the memory access circuit adjusts the memory access timing during a period of horizontal synchronizing signal or vertical synchronizing signal of the external synchronizing signal, or during a predetermined period after predetermined elapse of time since the horizontal synchronizing signal or the vertical synchronizing signal. Further, it is preferable that the memory access circuit adjusts the memory access timing in every predetermined number of horizontal synchronizing signals or vertical synchronizing signals, or in every predetermined time, in the display.

In accordance with another aspect of the present invention, there is provided a memory access circuit comprising a memory, a clock generator for generating a reference clock signal, a delay circuit for delaying the reference clock signal to create a delay clock signal (14), the delay circuit creating a plurality of delay clock signals of various delay values, a memory access test controller for supplying a memory test start signal in reply to the external synchronizing signal, a test data generator for generating test data, a data selector for selecting one of the external data and the test data and supplying the same data, a memory access controller for supplying a write control signal to the memory, a buffer, a data reading circuit for taking the data from the memory in synchronization with the reference clock signal, and a data comparator. The test data generator generates the test data in reply to the memory test start signal, supplies the test data in synchronization with the reference clock, and supplies the write data corresponding to the test data in synchronization with the reference clock. The memory access test controller supplies a data selector switching signal in reply to the external signal. The data selector switches the selector so as to supply the test data in reply to the data selector switching signal. The memory writes the test data supplied from the data selector in synchronization with the reference clock signal. The data reading circuit reads the test data from the memory in synchronization with each of the delay clock signals and supplies each of the read test data to the data comparator. The data comparator compares each of the read test data with the write data and notifies the memory access test controller of the comparison result. The memory access test controller determines a delay value of the delay circuit in reply to the notification and adjusts a memory access timing of the memory access circuit according to the decision.

The memory access test controller comprises a shift register for storing a delay value of the delay clock where the compared data results in agreement and adjusts a memory access timing of the memory access circuit according to the delay value stored in the shift register in reply to the notification.

When there exist a plurality of delay clocks where the compared data result in agreement, the memory access test controller comprises a first shift register for storing the delay value of the smallest delay for a reference clock, of the delay clocks resulting in agreement of the data and a second shift register for storing the delay value of the largest delay for the reference clock, and the memory access timing of the memory access circuit is adjusted according to the data stored in the first shift register and the data stored in the second shift register.

In order to solve the above problem, it is preferable that the memory access circuit is operated in the following operation method. This operation method comprises the steps of: creating a reference clock; delaying the reference clock signal to create a plurality of delay clocks of various delay values; supplying a memory test start signal in reply to an external synchronizing signal; creating the test data in reply to the memory test start signal; writing the test data in synchronization with the reference clock; reading the written test data from the memory in synchronization with the delay clock; comparing the test data with the read data; and selecting the delay clock according to a result of the comparison. In the operation method, an image signal is written into the memory and the image signal is read from the memory in synchronization with the selected delay clock.

Further, it comprises the steps of: creating a reference clock; supplying a memory test start signal in reply to an external synchronizing signal; generating the test data in reply to the memory test start signal; delaying the test data to create a plurality of delay test data of various delay values; writing the delay test data into a memory in synchronization with the reference clock; reading the written data from the memory; comparing the test data with the read data; and selecting the delay value according to a result of the comparison, wherein preferably an image signal is written with the selected delay value.

In accordance with further another aspect of the present invention, there is provided an operation method of a memory access circuit for a memory which specifies an input timing of input data according to an input data-strobe signal and specifies an output timing of output data according to an output data-strobe signal. The operation method comprises the steps of: supplying a memory test start signal in reply to an external synchronizing signal; creating test data in reply to the memory test start signal and entering the same data into the memory; entering the input data-strobe signal into the memory in synchronization with the test data; delaying the output data-strobe signal to create a plurality of delay output data-strobe signals of various delay values; reading the data entered into the memory in synchronization with the delay output data-strobe signal; comparing the test data with the read data; and selecting the delay output data-strobe signal according to a result of the comparison. In the operation method of a memory access circuit, a data signal is entered into the memory and the data signal is read from the memory in synchronization with the selected delay output data-strobe signal.

In accordance with further another aspect of the present invention, there is provided an operation method of a memory access circuit for a memory which specifies an input timing of input data according to an input data-strobe signal and specifies an output timing of output data according to an output data-strobe signal. The operation method comprises the steps of: supplying a memory test start signal in reply to an external synchronizing signal; creating test data in reply to the memory test start signal and entering the same data into the memory; entering the input data-strobe signal into the memory in synchronization with the test data; delaying the input data-strobe signal to create a plurality of delay input data-strobe signals of various delay values and entering the same signals into the memory; reading the data entered into the memory in synchronization with the delay output data-strobe signal; comparing the test data with the read data; and adjusting the memory access timing according to the above comparison.

It is preferable that the operation method of a memory access circuit comprises the step of adjusting the memory access timing between a front porch of the external synchronizing signal and a back porch of the external synchronizing signal.

It is preferable that the operation method of a memory access circuit, in which the external synchronizing signal includes a first signal and a second signal and has a blanking period including no data signal between the first signal and the second signal, comprises the step of adjusting the memory access timing during the blanking period.

It is preferable that in the operation method, the external synchronizing signal is a vertical synchronizing signal or a horizontal synchronizing signal.

In accordance with further another aspect of the present invention, there is provided an operation method of a memory access circuit. The operation method comprises the steps of: creating a reference clock; delaying the reference clock signal to create a plurality of delay clock signals of various delay values; supplying a memory test start signal in reply to the external synchronizing signal; selecting one of the external data and the test data and supplying it; supplying a write control signal to the memory; taking the data from the memory in synchronization with the reference clock signal; creating the test data in reply to the memory test start signal; supplying the test data in synchronization with the reference clock and supplying the write data corresponding to the test data in synchronization with the reference clock; supplying a data selector switching signal in reply to the external signal; switching the data selector so as to supply the test data in reply to the data selector switching signal; writing the tests data supplied from the data selector, into the memory in synchronization with the reference clock signal; reading the test data from the memory in synchronization with each of the delay clock signals; supplying each of the read test data to the data comparator; comparing each of the read test data with the write data; notifying the memory access test controller of the comparison result; deciding a delay value of the delay circuit according to the notification; and adjusting a memory access timing according to the decision.

According to the invention, the memory access circuit adjusts the memory access timing by using the synchronizing signal having the blanking periods in its front and rear portions, thereby advantageously adjusting the memory access timing without restricting the actual data processing.

Further, according to the invention, it is effective in performing a memory access with the optimum memory access timing in accordance with a change of clock delay caused by an environmental change in temperature and power voltage.

According to the invention, it is effective in controlling defects such as disturbance of video in the video processing requiring real time processing, which is easily affected by the environmental change.

### BRIEF DESCRIPTION OF THE DRAWINGS

FIG. 1 is a view showing one example of a system in which a memory access circuit is installed.

FIG. 2 is a view showing a structure of the memory access circuit.

FIG. 3 is a view showing a memory access test timing in an embodiment of the invention.

FIG. 4 is a view showing one example of operation waveforms of delay clock signals generated by a clock delay adjusting circuit.

FIG. 5 is a flow chart showing an operation of the circuit in the embodiment of the invention.

FIG. 6 is a view showing the structure of a TAP position shift register.

FIG. 7 is a view showing the judging condition of a delay value.

FIG. 8 is a block diagram showing a structure of a second embodiment.

FIG. 9 is a view showing an example of the structure of a judgment table.

FIG. 10 is a flow chart showing a test judgment operation.

FIG. 11 is a block diagram showing a structure of a third embodiment.

FIG. 12 is a timing chart showing an operation timing in the case of using a DQS signal.

FIG. 13 is a timing chart showing an operation timing in the case of using a DQS signal.

FIG. 14 is a block diagram showing an example of the structure of a plasma display 50 including the above-mentioned memory access circuit.

### DESCRIPTION OF THE PREFERRED EMBODIMENT

### FIRST EMBODIMENT

Hereinafter, best modes for carrying out the invention will be described with reference to the drawings.

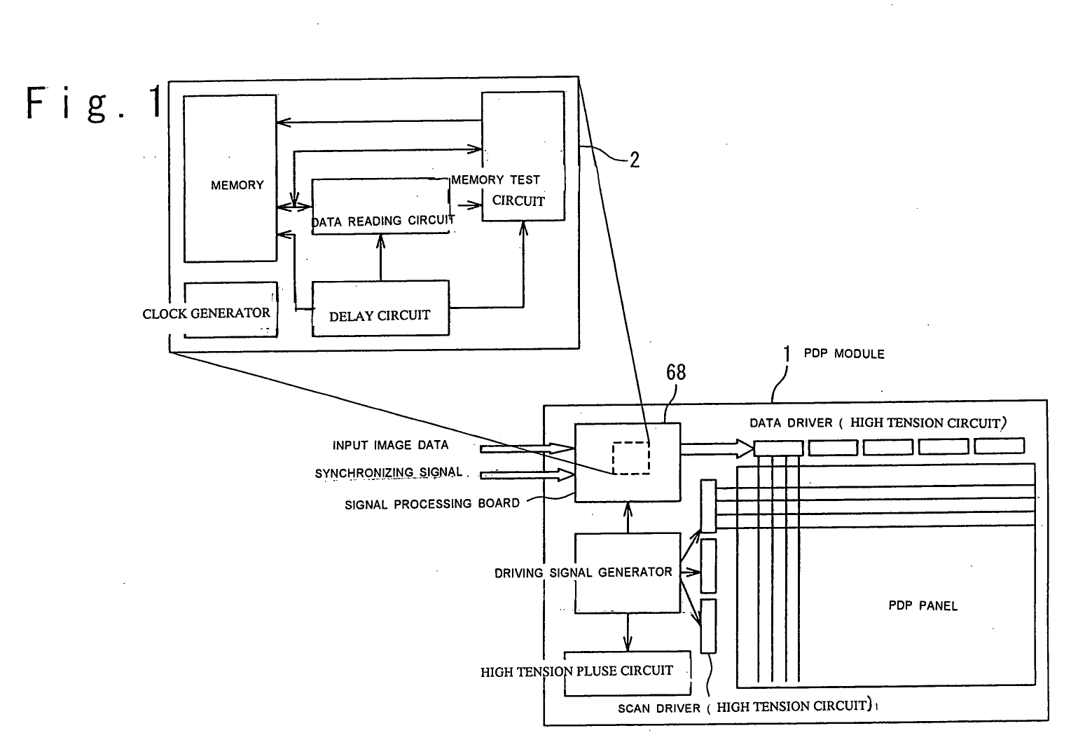

FIG. 1 is a view showing an example of a system on which a memory access circuit described in this embodiment is mounted. The device described in this embodiment works effectively on such a system that needs a frame memory of large capacity with a temperature change in its operating environment within the range of −10° C. to +80° C. and with various initial setting for power voltage in LSI. When the memory access circuit of this embodiment is mounted on, in particular, such a large-sized display system as being represented by a plasma display, it is effective in operating the system stably. In the following form of the embodiment, a description will be made in the case where the memory access circuit of the invention is mounted on a plasma display. This does not intend to restrict the system on which the memory access circuit 2 of the invention is mounted. With reference to FIG. 1, a system having the memory access circuit 2 comprises a plasma display module 1 and a memory access circuit 2 including a memory access test controller of this embodiment.

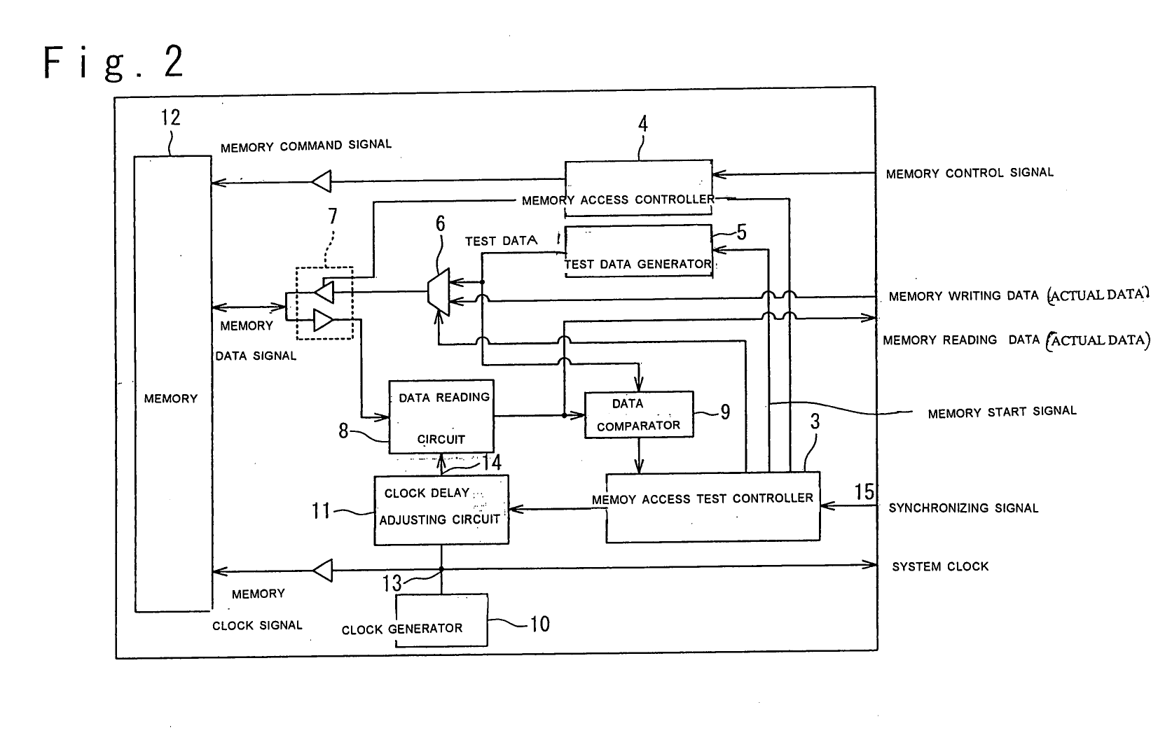

FIG. 2 is a view showing a circuit structure of the memory access circuit in this embodiment. With reference to FIG. 2, the memory access circuit 2 comprises a memory access test controller 3, a memory access controller 4, a test data generator 5, a data selector 6, an I/O buffer 7, a data reading circuit 8, a data comparator 9, a clock generator 10, a clock delay adjusting circuit 11, and a memory 12.

The memory access test controller 3 is a control function block for controlling a memory access test. The memory access test controller 3 has an input unit for receiving a synchronizing signal from the outward and a plurality of output units. Each of the output units is electrically connected to the memory access controller 4, the test data generator 5, the data selector 6, and the clock delay controller 11. The respective output units supply a control signal necessary for adjusting a memory access timing to the memory access controller 4, the test data generator 5, the data selector 6, and the clock delay adjusting circuit 11 through data lines. In the first embodiment, writing/reading of the actual data is controlled by the memory access controller 4 according to a memory control signal. Namely, writing/reading address data (address line is omitted in the drawing) is supplied by the memory access controller 4.

The memory access controller 4 is a control function block for controlling a memory access. The memory access control circuit 4 is connected to the memory access test controller 3, the I/O buffer 7, and the memory 12. The memory access controller 4 has an input unit for receiving a control signal from the memory access test controller 3 and an output unit for supplying a memory access control signal. The memory access controller 4 supplies the memory access control signal to the memory 12 in reply to the control signal from the memory access test controller 3. The memory access controller 4 is connected to the I/O buffer 7, so to supply a signal for controlling the I/O buffer 7 depending on necessity.

The test data generator 5 is a data generation function block for generating test data. The generated test data is used for adjusting a timing of memory access. The test data generator 5 has an input unit for receiving a signal supplied from the memory access test controller 3 and an output unit for supplying the generated test data to the memory 12 and the comparator 9. The input unit of the test data generator 5 is electrically connected to the output unit of the memory access test generator 3 through data lines. The output unit of the test data generator 5 is electrically connected to the data selector 6 and the comparator 9 through data lines.

The data selector 6 is a data switching function block for switching the data to be written into a memory. The data selector 6 is switched in reply to a data selector switching signal from the memory access test controller 3. The data to be written into a memory is switched from actual data to test data through switching of the selector. In this specification, the data to be written into a memory and to be read from a memory in the usual operation mode is referred to as “actual data”, while the data to be used for adjusting a memory access timing is referred to as “test data”. The data selector 6 switches the selector in reply to a data selector switching signal supplied from the memory access test controller 3 after completion of the timing adjustment of memory access. After completion of the timing adjustment, the data selector 6 switches the data to be written into a memory from the test data to the actual data by switching the selector.

The I/O buffer 7 is a buffer set between the devices of different throughputs. The I/O buffer 7 comprises an input unit, connected to the data selector 6, for receiving the data sent from the data selector 6, a data transmitting and receiving unit, connected to the memory 12, for transmitting and receiving data to and from the memory 12, and an output unit, connected to the data reading circuit (flip-flop) 8, for supplying the data read from the memory 12 to the data reading circuit 8. The I/O buffer 7 transmits the data supplied from the data selector 6 to the memory 12 at the time of writing data and transmits the data read from the memory 12 to the data reading circuit 8 at the time of reading data.

The data reading circuit 8 is a data taking function block for taking in the data written into the memory 12 through the I/O buffer 7. The data reading circuit 8 is connected to the I/O buffer 7. The data reading circuit 8 has an input unit for receiving the data supplied from the I/O buffer 7 and an output unit for supplying the taken data. The data reading circuit 8 takes in the data supplied from the memory 12 through the I/O buffer 7 in synchronization with a delay adjusted clock signal 14 which has been delay-adjusted by the clock delay adjusting circuit 9.

The data comparator 9 is a comparison function block for comparing the test data written into the memory 12 with the original test data in synchronization with the delay adjusted clock signal 14. The test data written into the memory 12 is supplied to the data comparator 9 through the I/O buffer 7. The original test data generated by the test data generator 5 is supplied to the data comparator 9. The data comparator 9 is connected to the data reading circuit 8, the test data generator 5, and the memory access test controller. The data comparator 9 has an input unit for receiving the data supplied from the data reading circuit 8 and an input unit for receiving the original test data supplied from the test data generator 5. The data comparator 9 also has an output unit for supplying the comparison results of received test data.

The clock generator 10 is a reference clock generation function block for generating a reference clock. The clock generator 10 supplies a clock signal used when a semiconductor integrated circuit transmits and receives data to and from the memory 12. The semiconductor integrated circuit writes the data to be written into the memory 12 at a predetermined address in synchronization with the clock signal supplied. The semiconductor integrated circuit reads out the data written into the memory 12 in synchronization with the clock signal supplied. Each function block operates in synchronization with the clock signal supplied from the clock generator 10.

The clock delay adjusting circuit 11 is a delay clock generation function block for generating a delay clock. The clock delay adjusting circuit 11 delays a reference clock signal supplied from the clock generator 10 to generate a delay clock. The clock delay adjusting circuit 11 has an input unit for receiving a reference clock signal and an output unit for supplying the generated delay clock signal to the data reading circuit 8. The clock delay adjusting circuit 11 can generate a plurality of delay clock signals of different delay values and generates a delay clock signal of predetermined delay value in reply to the delay clock generation signal supplied from the memory access test controller 3.

The memory 12 is a clock synchronous memory operating in synchronization with a clock signal supplied. For example, a reference clock signal 13 is entered to the memory 12 and the data stored in synchronization with the reference clock signal 13 is supplied from the memory 12.

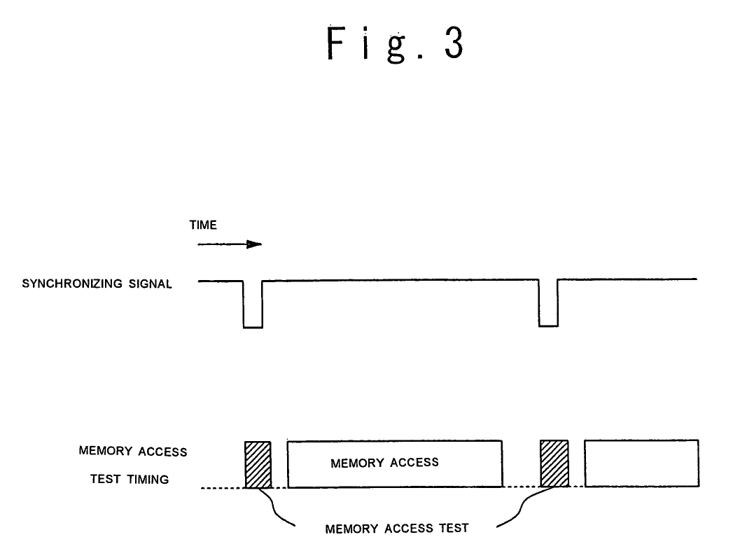

FIG. 3 is a view showing a memory access test timing in the embodiment of the invention. With reference to FIG. 3, a synchronizing signal in the embodiment of the invention has blanking periods before and after the synchronizing signal. In the blanking periods, there is no data to be processed. In synchronization with this synchronizing signal, memory access timing can be adjusted without restricting the actual data processing. This embodiment will be described taking an example of an image synchronizing signal having no effective image data to be displayed on a display before and after the synchronizing signal. Video processing for processing the video data supplied in synchronization with the image synchronizing signal is the actual data processing described in the following explanation. A video synchronizing signal, in particular, a vertical synchronizing signal or a horizontal synchronizing signal has a period including no display of image, which is called a blanking period (vertical blanking period or horizontal blanking period). A memory access timing is adjusted in synchronization with this image synchronizing signal, which enables the adjustment of a memory access timing without restricting the original video processing.

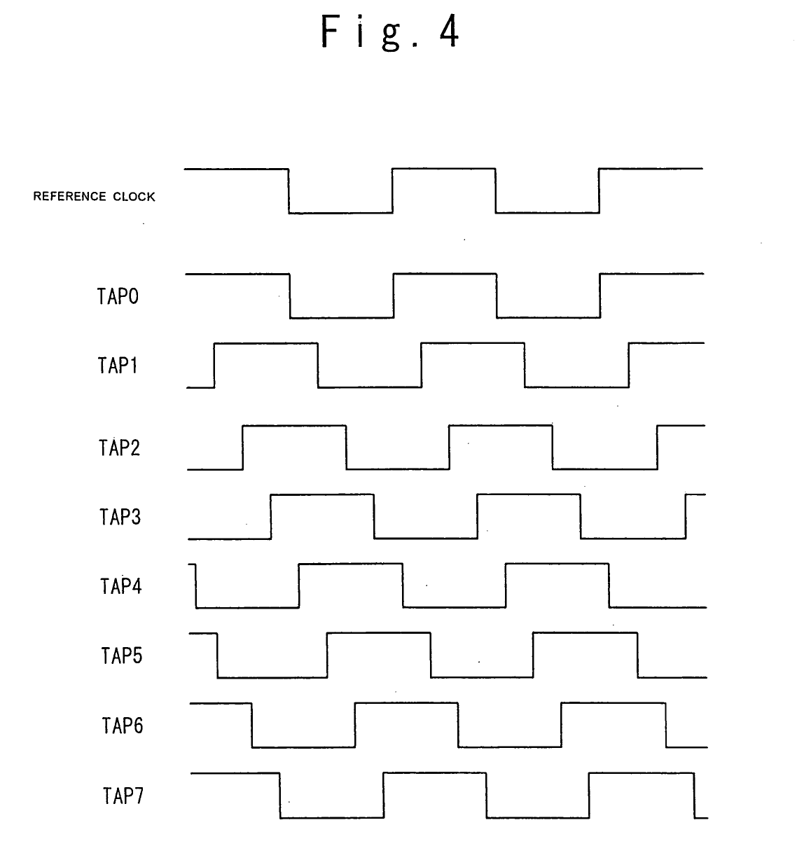

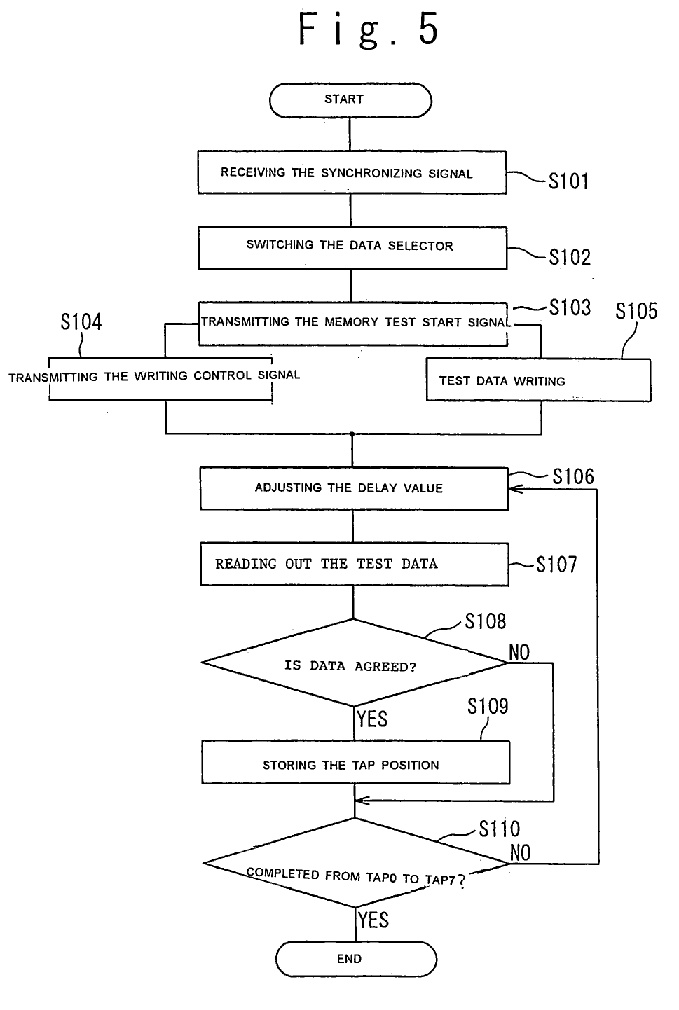

FIG. 4 is a view showing an example of operation waveforms of delay clock signals generated by the clock delay adjusting circuit 11. As illustrated in FIG. 4, the clock delay adjusting circuit 11 generates delay clocks of different delay values while switching the setting in eight ways from TAP0 to TAP7. The delay value of the delay clock set in the TAP0 is almost zero and the delay value of the delay clock set in the TAP7 is the value corresponding to almost one cycle of memory clock. The clock delay adjusting circuit 11 equally divides this range of delay into each delay of TAP1 to TAP6. Setting of the number of delay values for one cycle of clock can be changed depending on the performance of a circuit requested by a semiconductor integrated circuit using the memory access circuit. The clock delay adjusting circuit 11 for supplying the operation waveforms shown in FIG. 5 switches the setting in eight ways of TAP0 to TAP7. The number of the delay values can be arbitrarily changed by changing the setting of the clock delay adjusting circuit 11.

Operation of the First Embodiment

FIG. 5 is a flow chart showing an operation of the circuit in this embodiment of the invention. With reference to FIG. 5, an operation of the memory access circuit described in this embodiment starts when the memory access controller 3 receives the synchronizing signal 15 (hereinafter, referred to as an external synchronizing signal) supplied from the outside. In Step S101, upon receipt of the external synchronizing signal 15, the memory access test controller 3 responds to the external synchronizing signal 15 to create a data selector switch signal and a memory test start signal. In Step S102, the memory access test controller transmits the data selector switch signal to the data selector 6. The data selector 6 having received the data selector switch signal from the memory access test controller 3 switches the data selector 6 in reply to the data selector switch signal and transmits the output from the test data generator 5 to the memory 12. In Step S103, the memory access test controller 3 transmits the created memory test start signal to the memory access controller 4 and the test data generator 5.

The memory access controller 4 receives the memory test start signal in Step S104. The memory access controller 4 transmits a memory writing control signal to the memory 12 upon receipt of the memory test start signal. The test data generator 5 creates test data upon receipt of the memory test start signal in Step S105. The test data generator 5 writes the test data into the memory 12 and supplies the same data to the data comparator 9 in synchronization with a reference clock signal. The memory access controller 4 notifies the clock delay adjusting circuit 11 of the completion of transmission upon completion of transmission of the memory writing control signal. The test data generator 5 notifies the clock delay adjusting circuit 11 of the writing completion upon completion of writing the test data.

In Step S106, the clock delay adjusting circuit 11 starts adjustment of the clock delay value. The clock delay adjusting circuit 11 can create a plurality of delay clocks of different values. The clock delay adjusting circuit 11 creates a delay clock of delay value 0 for a reference clock signal at the time of starting the adjustment of the clock delay value and supplies it to the data reading circuit 8. The data reading circuit 8 reads out the test data from the memory 12 in synchronization with the supplied delay clock signal. In Step S107, the data reading circuit 8 supplies the test data read out from the memory 12 to the data comparator 9.

In Step S108, the data comparator 9 compares the test data supplied from the data reading circuit 8 with the test data supplied from the test data generator 5 (original test data). There may be a deviation between the timing of the test data supplied by the test data generator 5 and the timing of the test data supplied by the data reading circuit 8. The data comparator 9 temporarily stores the test data (original data) supplied from the test data generator 5 to the data comparator 9. The data comparator 9 compares the stored data with the test data supplied from the data reading circuit 8. As a result of the comparison, in the case of agreement between the stored data and the test data, the processing proceeds to Step S109. In Step S109, the data comparator 9 notifies the memory access test controller 3 of the delay value of the delay clock at the agreement time. The memory access test controller 3 stores the notified delay value. In Step S108, in the case of disagreement between the stored data and the test data, the data comparator 9 notifies the memory access test controller 3 of the disagreement and the processing proceeds to Step S110.

In Step S110, upon receipt of the notice of comparison completion, the memory access test controller 3 responds to the notice of the comparison completion, so to detect the current delay value. The memory access test controller 3 verifies whether the comparison of the data has been completed as for all the possible delay clocks created by the clock delay adjusting circuit 11. As a result of the verification, when there exists a delay value that has not been compared with the test data yet, the memory access test controller 3 supplies a creating instruction of a delay clock of a delay value different from the current delay value to the clock delay adjusting circuit 11. After the delay clock creating instruction is supplied from the memory access test controller 3, the processing is returned to Step S106.

In Step S110, as a result of the verification, when the data comparison has been completed as for all the possible delay clocks created by the clock delay adjusting circuit 11, the data comparison processing is finished.

FIG. 4 is a view showing various waveforms of a plurality of delay clocks which the clock delay adjusting circuit 11 creates. The operation of the memory access circuit in the embodiment of the invention, shown in FIG. 5 is as follows when the respective delay clocks correspond to the respective clock signals of the operation waveforms shown in FIG. 4. In Step S106 of FIG. 5, the clock delay adjusting circuit 11 responds to an instruction from the memory access test circuit having received the synchronizing signal 15, to create a delay clock with the TAP position set at the TAP0. In Step S107, the data reading circuit 8 reads out the test data from the memory 12 in synchronization with the delay clock of TAP0 and the processing proceeds to Step S108. When the data comparison has been finished in Step S108, resulting in agreement, the processing proceeds to Step S109. The memory access test controller 3 stores the TAP position at that time. When the data comparison has been finished in Step S108, resulting in disagreement, the memory access test controller 3 proceeds to Step S110 without storing the TAP position.

In Step S110, the data comparator 9 notifies the memory access controller 4 that the comparison has been finished at TAP0. Since the TAP position is TAP0 and the comparison has not been completed on the delay clocks with the TAP positions other than TAP0, the processing is returned to Step S106.

In Step S106, the memory access test controller 3 responds to the notification result that the comparison has been completed at TAP0, from the data comparator 9, so to instruct the clock delay adjusting circuit 11 to create a clock signal with the TAP position set at TAP1. In reply to the instruction of creating a clock signal of TAP1, the clock delay adjusting circuit 11 supplies the clock signal of TAP1 to the data reading circuit 8, the comparison of the data is performed similarly to the case of TAP0, and thereafter, the same processing as the above mentioned processing will be repeated over the clock signal of TAP7.

FIG. 6 is a view showing a structure of a shift register for detecting the intermediate TAP position from the range of the TAPs where the memory access writing data agrees with the reading data. With reference to FIG. 6, the TAP intermediate position judgment is performed by using a TAP position shift register MIN 16 and a TAP position shift register MAX 17. The TAP position shift register MIN 16 stores the first TAP position of getting agreement in the comparison data and shifts the position in the direction from TAP0 to TAP7 at the time of judging the TAP intermediate position. The TAP position shift register MAX 17 stores the last TAP position of getting agreement in the comparison data and shifts the position in the direction from TAP7 to TAP0 at the time of judging the TAP intermediate position.

The data comparator 9 compares each reading data with each writing data as for all the delay clock signals, and notifies the memory access test controller 3 of the comparison result. In reply to the notification of the comparison result, the memory access test controller 3 stores each TAP position of getting agreement with each test data. When the reading data is compared with the writing data in synchronization with a plurality of delay clocks of various delay values, the TAP position where the reading data agrees with the writing data can be obtained continuously to the range of some buffer output.

At this time, the TAP position shift register MIN 16 sets “1” at the first TAP position of the data agreement and sets “0” at the other TAP positions. Similarly, the TAP position shift register MAX 17 sets “1” at the last TAP position of the data agreement and sets “0” at the other TAP positions.

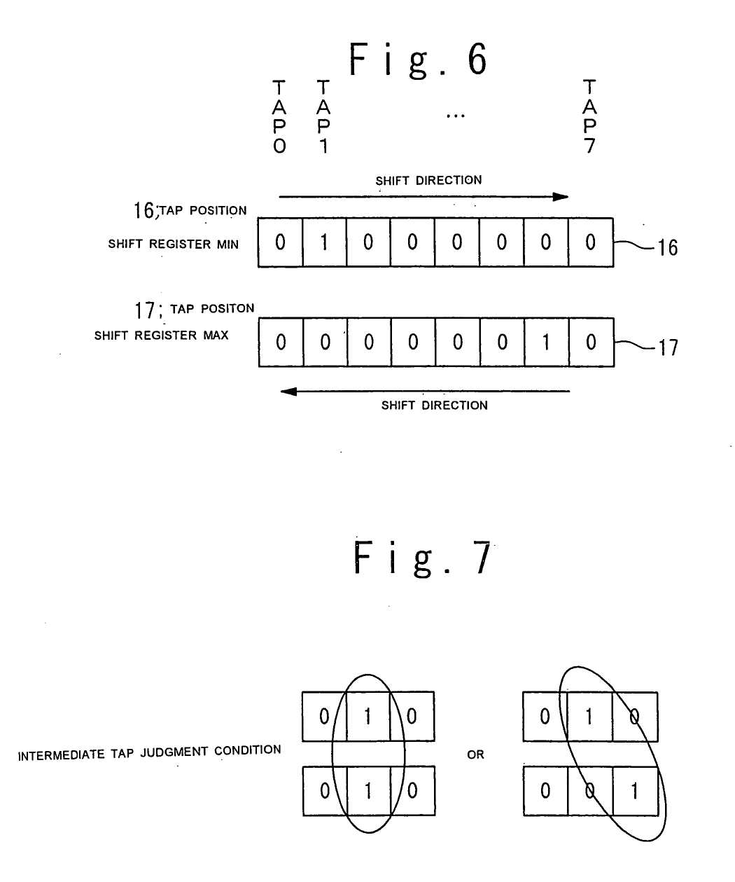

Judgment is performed whether “1” exists at the same TAP positions in the TAP position shift register MIN 16 and in the TAP position shift register MAX 17, or whether “1” of the TAP position shift register MAX 17 exists at the TAP position next to “1” in the TAP position shift register MIN 16. (FIG. 7) When it does not satisfy the above TAP position judging condition shown in FIG. 7, the TAP position shift register MIN 16 shifts the position in the direction from TAP0 to TAP7, while the TAP position shift register MAX 17 shifts the position in the direction from TAP7 to TAP0, and then the above judgment is performed again. The above shift operation and judgment operation will be repeated until the above TAP position judging condition is satisfied. The clock delay circuit is set at the TAP position of “1” in the TAP position shift register MIN 16 which satisfies the judging condition, so to gain an ordinary memory access, thereby adjusting a clock delay.

As mentioned above, according to the invention, it is possible to adjust a memory access timing without restricting the performance of data processing. Even when a delay value is deviated from the intended delay value according to a change of the ambient temperature during the operation of the memory access circuit and a change of the delay value due to a change of power voltage, it is possible to form a digital circuit capable of gaining access to a memory without changing an operation margin. It is effective, in particular, when a high speed memory with rigid operation margin is used. The invention adjusts a memory access timing while using a synchronizing signal including no data to be processed in its front and rear portions. Therefore, it is possible to adjust a memory access timing without restricting the actual data processing by performing the adjustment of a memory access timing in synchronization with this synchronizing signal.

In the embodiment, upon receipt of an external synchronizing signal, it starts the adjustment of a memory access timing with test data, described in the flow chart of FIG. 5. In the case of a display such as a monitor and a TV, an external synchronizing signal corresponds to a vertical synchronizing signal or a horizontal synchronizing signal of an image signal. The period of a synchronizing signal of vertical synchronizing signal or horizontal synchronizing signal does not include a display signal, namely, the actual data referred to in this specification. When adjustment of a memory access timing is completed during the synchronizing signal period, it can be adjusted without having an effect on the processing of the actual data. The embodiment can swiftly cope with a temperature rise inside the device and a change of power voltage while readjusting a memory access timing regularly.

An external synchronizing signal may be a signal such that one vertical synchronizing signal or one horizontal synchronizing signal is to be input per every predetermined number of vertical synchronizing signals or horizontal synchronizing signals. Or, it may be a signal to be input in synchronization with a horizontal synchronizing signal, in every predetermined time, for example, in every three seconds. When the memory access circuit of the embodiment is applied to the other device than a display, an external synchronizing signal may be a signal to be input in every predetermined time in synchronization with the blanking periods where the actual data to be processed by the memory is not received. Or it may be a timing signal to be input at every detected timing after detecting an environmental change such as a temperature rise inside the device and a change of power voltage which may cause a change in a memory access timing. In any case, it is important that an external synchronizing signal should be input within the blanking period where the actual data to be processed by the memory is not received and that adjustment of a memory access timing has been completed during the period. Adjustment of a memory access timing can be divided and performed over a plurality of periods of external synchronizing signal. It is needless to say that the above memory access timing adjustment of the other device than a display can be also applied to a display.

### SECOND EMBODIMENT

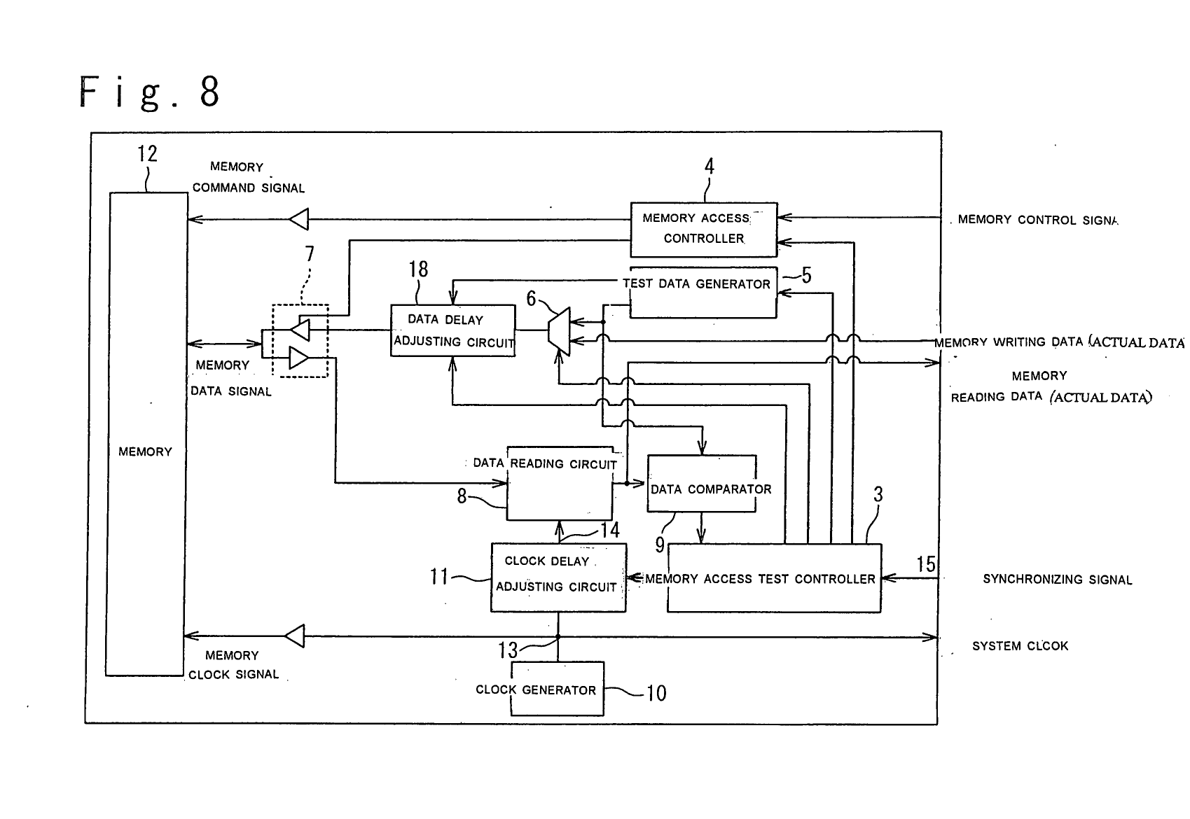

Hereinafter, a second embodiment of the invention will be described with reference to the drawings. FIG. 8 is a block diagram showing a structure of the second embodiment. A memory access circuit in the second embodiment is provided with a data delay circuit 18 in addition to the memory access circuit shown in the first embodiment. As illustrated in FIG. 8, the data delay circuit 18 is connected between the data selector 6 and the I/O buffer 7. Memory writing data is supplied to the data delay circuit 18 from the data selector 6 and writing test data is supplied there from the test data generator 5. In reply to a writing test start signal supplied from the memory access test controller 3, the data delay circuit 18 performs a data writing test. Based on the result of the writing test, the data delay circuit 18 delays the memory writing data and writes it into the memory 12. In the second embodiment, writing/reading of the actual data is performed while controlling the memory access controller 4 with a memory control signal. That is to say, the memory access controller 4 performs the output of the writing/reading address data (the address line is omitted in the drawing).

The writing test operation of the memory access circuit described in the second embodiment starts when the memory access test controller 3 receives a synchronizing signal 15 (hereinafter, referred to as an external synchronizing signal) supplied from the outside. Upon receipt of the external synchronizing signal 15, the memory access test controller 3 responds to the external synchronizing signal 15, to create a writing test start signal. The memory access test controller 3 transmits the created writing test start signal to the test data generator 5 and the data delay adjusting circuit 18. The data delay adjusting circuit 18 starts the adjustment of data delay upon receipt of the writing test start signal supplied from the memory access test controller 3.

The test data generator 5 creates writing test data upon receipt of the writing test start signal. The test data generator 5 transmits the writing test start signal to the data delay adjusting circuit 18 in synchronization with a reference clock signal.

The data delay adjusting circuit 18 starts the adjustment of a clock delay value. The data delay adjusting circuit 18 creates a plurality of delay clocks of various delay values and it can delay the memory writing data according to each of the delay clocks. The data delay adjusting circuit 18 compares the writing test data supplied in synchronization with the reference clock with the memory writing data. The data delay adjusting circuit 18 determines the amount of delay of the memory writing data based on the comparison and supplies the memory writing data to the memory 12 in synchronization with the delay clock corresponding to that delay amount.

As mentioned above, the memory access circuit in the second embodiment can perform a test of the data reading operation from the memory 12 and a data writing test into the memory 12 at the same time. Judgment of the tests will be hereafter described in the case of simultaneously performing the data reading test and the data writing test on the memory 12.

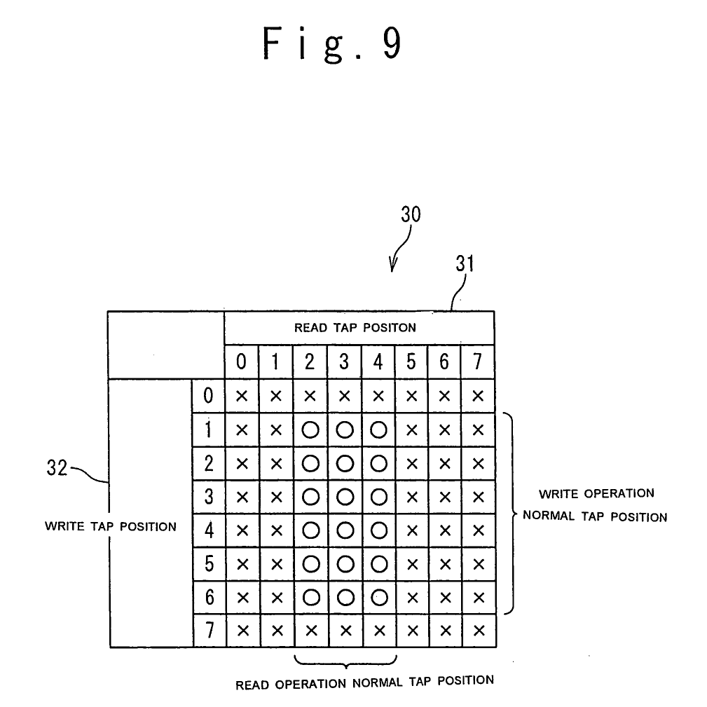

FIG. 9 is a view illustrating a structure of a judgment table 30 used for judgment of the tests when performing the reading/writing tests. As illustrated in FIG. 9, the judgment table 30 includes a reading judgment area 31 and a writing judgment area 32. The judgment table 30 shown in FIG. 9 is a table created when a writing test and a reading test are performed in accordance with a plurality of delay clocks from delay amount 0 to delay amount 7.

A case where the data writing/reading has been performed normally and the other case where it has not been done normally, are represented by two values, each of which is stored in each corresponding cell of the judgment table 30. FIG. 9 shows the above two values with O and x conceptually.

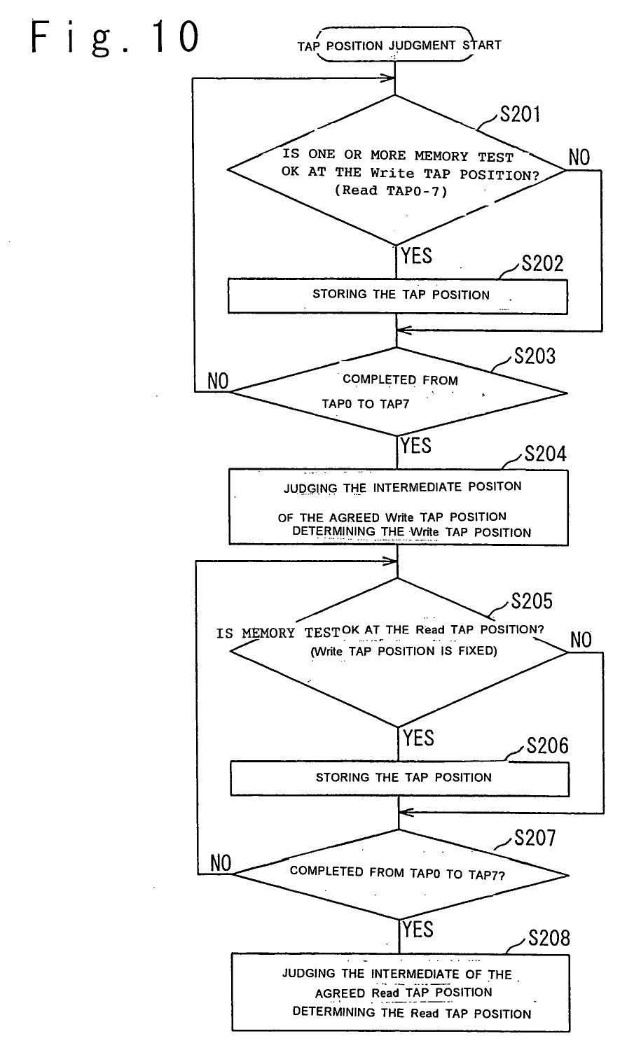

FIG. 10 is a flow chart showing the test judgment operation using the above judgment table 30. In Step S201 of FIG. 10, WriteTAP position is specified and the memory test result from ReadTAP0 to ReadTAP7 corresponding to the WriteTAP position is sampled. A judgment whether the TAP where writing has been normally performed exists or not is made with reference to the sampled memory test result. As a result of the judgment, when there exists the TAP where writing has been normally performed, the corresponding TAP position is stored (Step S202). When there exists no such TAP at the specified WriteTAP position, the processing proceeds to Step S203.

In Step S203, whether the sampling of the test results has been completed at all the WriteTAP positions is judged. As a result of the judgment, when every sampling of the test results from WriteTAP0 to WriteTAP7 has been completed, the processing proceeds to Step S204, while when there exists any WriteTAP where sampling of the test result has not been completed, the processing is returned and the operation from Step S201 will be continued. In Step S204, the WriteTAP position corresponding to the intermediate position is determined (fixed) according to the stored WriteTAP position.

In Step S205, the test result of the ReadTAP corresponding to the decided WriteTAP position is sampled. Whether the data can be read normally or not is checked according to the test result of the sampled ReadTAP. As a result of the judgment, when data can be normally read at the ReadTAP position, it proceeds to Step S206 and the corresponding ReadTAP position is stored. After storing is completed in Step S206, the processing proceeds to Step S207. When the data cannot be normally read at the ReadTAP position according to the test result of the sampled ReadTAP in Step S205, it proceeds to Step S207.

Whether the sampling of the test results has been completed at all the ReadTAP positions or not is checked in Step S207. As a result of the check, when all the sampling of the test results from the ReadTAP0 to the ReadTAP7 has been completed, the processing proceeds to Step S208, while when there exists any ReadTAP where sampling of the test result has not been completed yet, the processing is returned and the operation from Step 205 will be continued. A ReadTAP position corresponding to the intermediate position is determined (fixed) according to the stored ReadTAP position, in Step S208.

According to the above operation, judgment can be properly performed in the case of simultaneously performing a data reading test and a data writing test on the memory 12. It is possible to read/write the data more accurately by forming a memory access circuit as mentioned above and performing a data reading test from the memory and a data writing test into the memory.

### THIRD EMBODIMENT

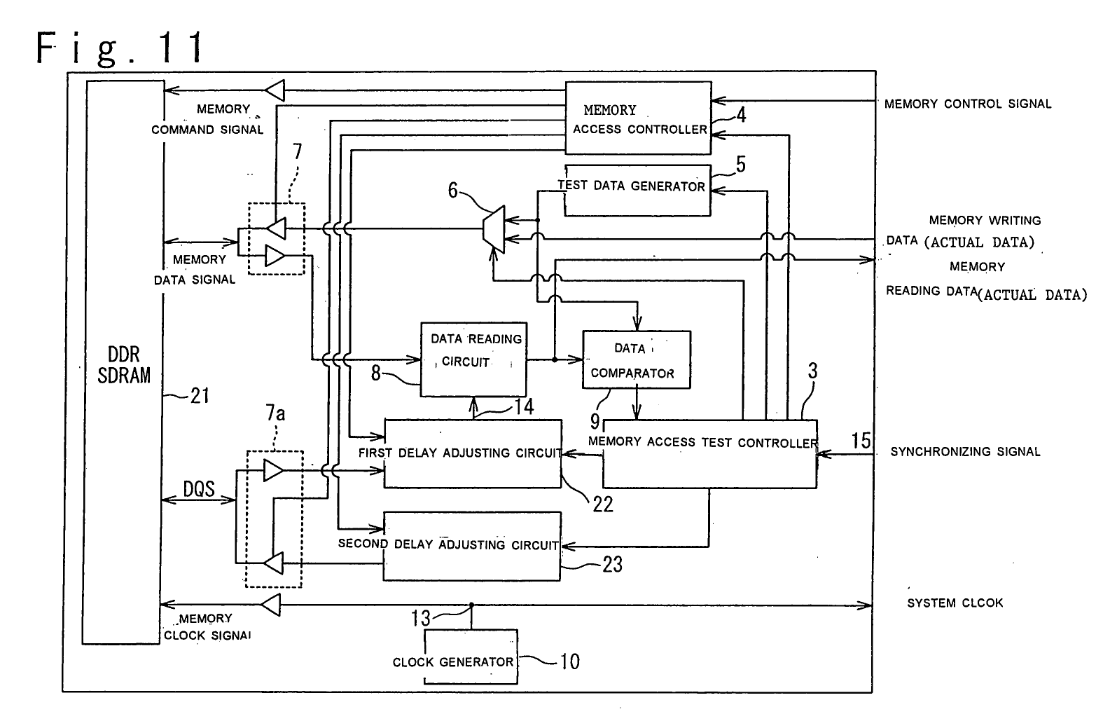

FIG. 11 is a block diagram showing a structure of a third embodiment of the invention. As illustrated in FIG. 11, a memory access circuit of the third embodiment comprises a DDR SDRAM 21, a first delay adjusting circuit 22, a second delay adjusting circuit 23, and an I/O buffer 7a. The DDR SDRAM 21 is an SDRAM capable of exchanging data at the double cycle of an external clock. The DDR SDRAM 21 adopts a DQS (Data Strobe Signal) in order to realize a high speed data transfer. In the case of writing data into the DDR SDRAM 21, the external memory access circuit supplies an input DQS to a DQS terminal in synchronization with the input of the writing data and the writing address data into the DDR SDRAM 21. In the case of reading data from the DDR SDRAM 21, when the external memory access circuit enters the read address data to the DDR SDRAM 21, the DDR SDRAM 21 supplies the reading data as well as an output DQS to the DQS terminal in synchronization with the reading data. Thus, the DDR SDRAM 21 notifies a receiver of the timing for transferring data by using the DQS. The DQS is a bidirectional strobe signal and works as an operation reference clock of data input and output at the data reading/writing time. The memory access circuit of the third embodiment can read and write data in accordance with the deviation when the DQS is deviated from a desired delay value caused by an ambient temperature change and a change of power voltage during the operation of the circuit.

In FIG. 11, the writing/reading of the actual data is performed by controlling the memory access controller 4 with a memory control signal. In other words, the memory access controller 4 performs the output of the writing/reading address data (the address line is omitted in the drawing) and the input DQS (input DQS before being delayed by the second delay adjusting circuit 23).

As illustrated in FIG. 11, the DDR SDRAM 21 is connected to the I/O buffer 7a through a data line. The I/O buffer 7a is the same buffer as the I/O buffer 7. The first delay adjusting circuit 22 is a timing control function block for controlling a data reading timing based on the DQS supplied from the DDR SDRAM 21. The first delay adjusting circuit 22 delays the DQS supplied from the DDR SDRAM 21, so to create a delay clock (hereinafter, referred to as a delay DQS). The first delay adjusting circuit 22 comprises an input unit for receiving the DQS from the DDR SDRAM 21 and an output unit for supplying the created delay DQS to the data reading circuit 8. The first delay adjusting circuit 22 can create a plurality of delay DQSs of various delay values and create a delay DQS of predetermined delay value in reply to the delay DQS signal supplied from the memory access test controller 3.

The second delay adjusting circuit 23 is a clock control function block for controlling the DQS supplied to the DDR SDRAM 21 based on the clock signal supplied from the clock generator 10. The memory writing data supplied to the DDR SDRAM 21 is supplied in synchronization with the reference clock. The second delay adjusting circuit 23 creates a proper DQS and supplies it to the DDR SDRAM 21 according to the reference clock supplied from the clock generator 10.

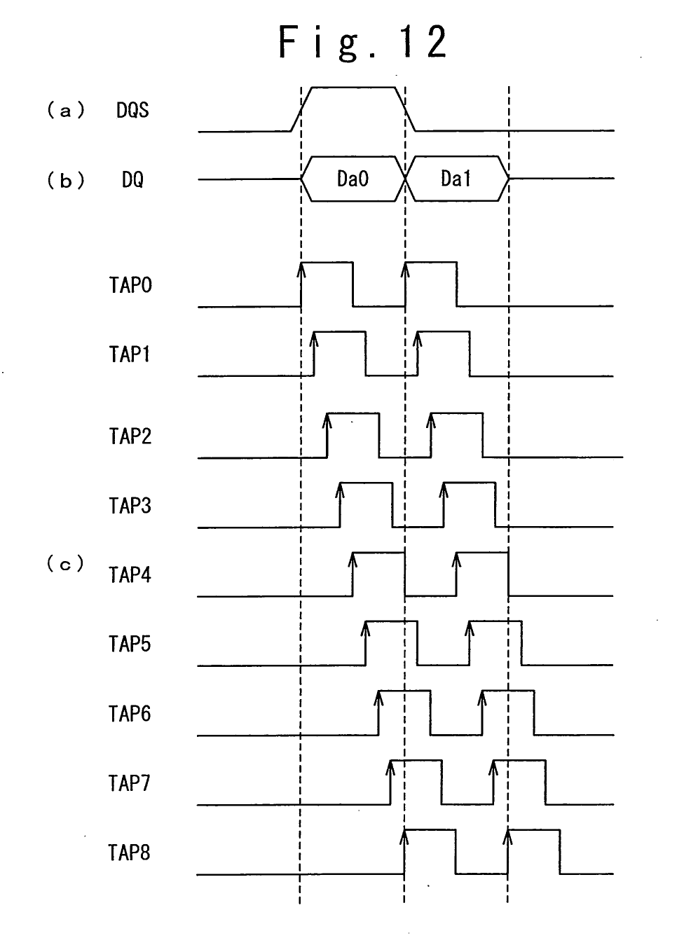

FIG. 12 is a timing chart showing the timing for adjustment clock when adjusting an operation timing of the DQS signal and a data reading timing. The adjustment clock (FIG. 12(c)) is used for adjusting a timing when reading data from the DDR SDRAM 21 in accordance with the DQS signal. FIG. 12(a) shows the waveform of the DQS signal. FIG. 12(b) shows waveforms of the timing when the data DQ is supplied. FIG. 12(c) shows waveforms of the timing of a delay clock used for performing the delay adjustment at the reading time according to the DQS.

When reading the data, the DQS supplied from the DDR SDRAM 21 rises up at the timing when the first data Qa1 of the data DQ is supplied, as illustrated in FIG. 12. The DQS falls down at the timing when the next data Qa2 is supplied. When adjustment of delay of the DQS signal is not performed, the memory access circuit takes in the data Qa1 at the intermediate timing (the timing of TAP4 in FIG. 12(c)) between the rising edge and the falling edge of the DQS signal.

The memory access circuit in the third embodiment creates a plurality of read clocks (TAP0 to TAP8) with each delay amount deviated equally during the period from the rising edge to the falling edge of the DQS signal, as illustrated in FIG. 12(c). A clock of a proper delay amount in the data reading can be specified through reading the test data at each timing of these read clocks.

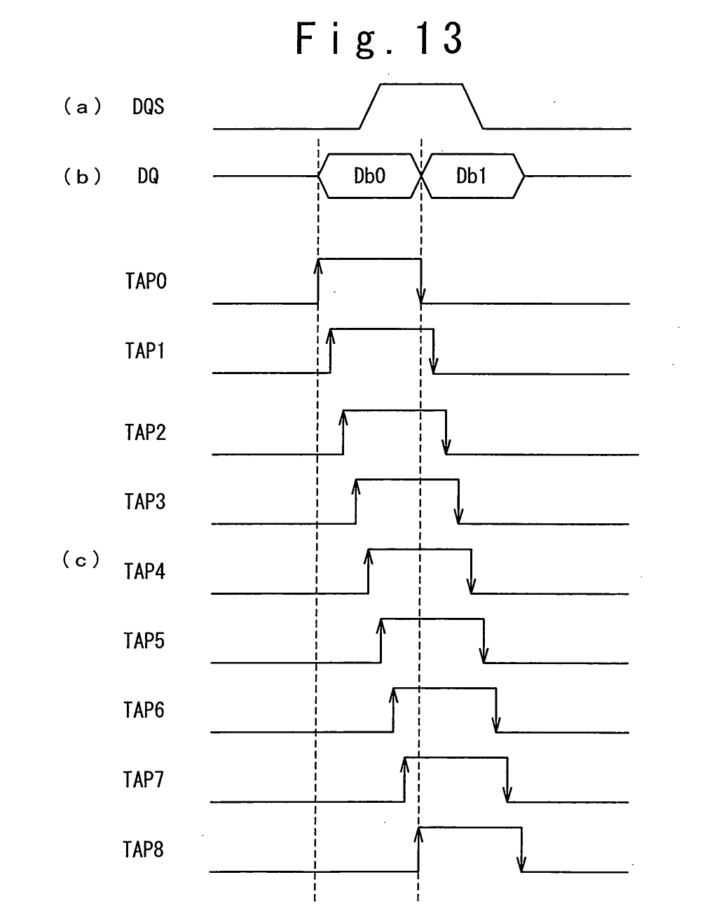

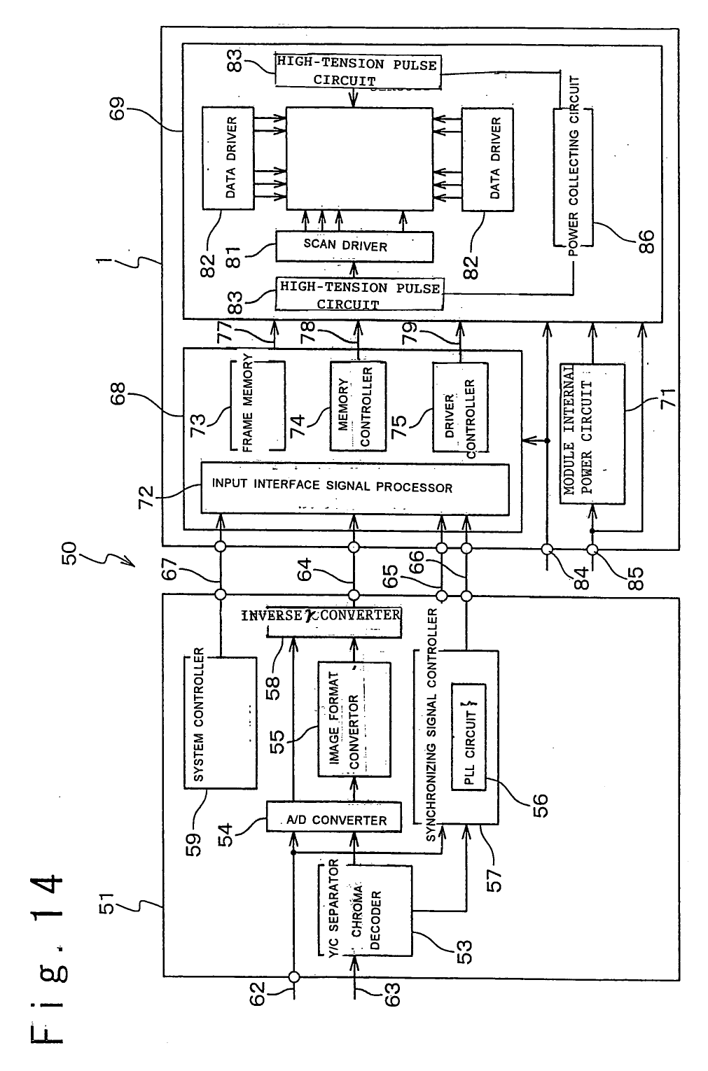

FIG. 13 is a timing chart showing an operation timing in the case of writing data into the DDR SDRAM 21. FIG. 13(a) shows an operation waveform of the DQS signal. FIG. 13(b) shows waveforms of the data supply timing in the case of writing the data DQ into the DDR SDRAM 21. FIG. 13(c) shows waveforms of a timing of a delay clock used for performing the delay adjustment at the time of writing the data according to the DQS.

As illustrated in FIG. 13, the DQS signal rises up just about in the center of the output timing of the first data Db0. It falls down in the center of the output timing of the next data Db1. The memory access circuit creates a reference DQS signal (signal at the timing TAP0 in FIG. 13(c)) rising up at the output timing of the data Db0 and falling down at the output timing of the data Db1 as mentioned above and supplies it to the second delay clock adjusting circuit 23 in the memory access control circuit 4. The second delay clock adjusting circuit 23 creates a plurality of write clocks (TAP0 to TAP8) in accordance with the reference DQS signal. In the write clocks shown in FIG. 13(c), the TAP0 indicates a signal without delay and the TAP8 indicates a signal rising up at the output completion timing of the data Dbq and falling down at the output completion timing of the data Db1. The second delay clock adjusting circuit 23 creates a plurality of write clocks (TAP0 to TAP8) with each delay amount deviated equally during the period from the rising time at TAP0 and the falling time at TAP8.

A reading test operation of the memory access circuit described in the third embodiment is the same as the operation in the first embodiment when the DQS signal is considered to correspond to the reference clock. The writing test operation is the same as the operation in the second embodiment when the DQS signal is considered to correspond to the reference clock. Further, also in the case of simultaneously performing the data reading test and the data writing test on the DDR SDRAM 21, test results are judged using the same table as the above judgment table 30.

As mentioned above, the memory access circuit described in the third embodiment comprises the first delay adjusting circuit 22 and the second delay adjusting circuit 23 for adjusting a delay amount of a DQS signal when data is read and written by using the DQS signal. The first delay adjusting circuit 22 (or the second delay adjusting circuit 23) performs the delay adjustment according to a change in the delay of the DQS signal. As a result, even when the DQS signal is deviated from a desired delay value owing to an ambient temperature change and a change of power voltage, data can be properly read and written.

FIG. 14 is a block diagram illustrating a structure of a plasma display 50 including the above mentioned memory access circuit. As illustrated in FIG. 14, the plasma display 50 is designed in modules. The plasmas display 50 designed in modules is formed by an analog interface 51 and a PDP (plasma display panel) module 1.

The analog interface 51 is formed by a Y/C separator 53 having a chroma decoder, an A/D converter 54, an image format converter 55, a synchronizing signal controller 57 having an PLL circuit 56, an inverse y converter 58, and a system controller 59. After converting the received analog video signal (analog RGB signal 62 and analog video signal 63) into the digital video signal, the analog interface 51 supplies the digital video signal 64 to the PDP module 1. More specifically, after being separated into luminance signals of each RGB color by the Y/C separator 53, the analog video signal 63 issued from a TV tuner is converted into a digital signal 64 by the A/D converter 54. When the pixel structure of the PDP module 1 is different from the pixel structure of the analog video signal 63, the digital signal 64 is converted into a proper image format by the image format converter 55.

The analog video signal 63 does not include a sampling clock for A/D conversion nor a data clock signal. The PLL circuit 56 included in the synchronizing signal controller 57 creates a sampling clock 65 and a data clock signal 66 with reference to the horizontal synchronizing signal supplied together with the analog video signal 63. The sampling clock 65 and the data clock signal 66 are supplied from the analog interface 51 to the PDP module 1. The system control circuit 59 creates various control signals 67. The control signal 67 is supplied from the analog interface 51 to the PDP module 1.

The PDP module 1 is formed by a digital signal processing board 68, a panel portion 69, and a module internal power circuit 71 including a DC/DC converter. The panel portion 69 includes an existing plasma display panel. The digital signal processing board 68 is formed by an input interface signal processor 72, a frame memory 73, a memory controller 74, and a driver controller 75. The average brightness level of the digital video signal 64 supplied from the analog interface 51 to the input interface signal processor 72 is calculated by an input signal average brightness level calculator (not illustrated) of the input interface signal processor 72 and supplied as the data of proper bit (for example: 5 bits).

The digital signal processing board 68 processes an existing signal in the input interface signal processor 72 and then transmits the processed control signal 77 to the panel portion 69. The memory controller 74 and the driver controller 75 create a memory control signal 78 and a driver control signal 79 respectively and transmit them to the panel portion 69 at the same time with the transmission of the processed control signal 77.

The panel portion 69 is formed by a plasma display panel, a scan driver 81 (installed integrally with the panel portion 69) for driving a scan electrode and a data driver 82 (installed integrally with the panel portion 69) for driving a data electrode. The panel portion 69 further includes a high-tension pulse circuit 83 for supplying a pulse voltage to the plasma display panel, the scan driver 81, and the data driver 82. The high-tension pulse circuit 83 is disposed and installed at several positions of the panel portion 69 as a part of the panel portion 69.

The plasma display panel has 1365×768 pixels aligned in 1365×768. The plasma display panel displays a predetermined image while the scan driver 81 controls the scan electrodes 36 and the data driver 82 controls the data electrodes 42 so as to turn on and off the predetermined pixels of the above number of pixels.

The plasma display panel, the scan driver 81, the data driver 82, and the high-tension pulse circuit 83 are arranged on one board forming the main body of the panel portion 69 and mounted there together with a power collecting circuit 86. The panel portion 69 is formed by integrating the plasma display panel, the scan driver 81, the data driver 82, the high-tension pulse circuit 83, and the power collecting circuit 86 with its main body. The digital signal processing board 68 is isolated from the panel portion 69 and mechanically independent.

The module internal power circuit 71 is isolated from the digital signal processing board 68 and the panel portion 69 and mechanically independent. The digital signal processing board 68, the panel portion 69, and the module internal power circuit 71 are integrally assembled as one module. The PDP module 1 is one module thus assembled. The analog interface 51 is isolated from the PDP module 1 and mechanically independent. The PDP module 1 is electrically connected to the analog interface 51 by electric wiring for transferring the control signal 67, the digital video signal 64, the sampling clock 65, the data clock signal 66, and the other signal.

After the analog interface 51 and the PDP module 1 are separately formed, the analog interface 51 and the PDP module 1 are built in the body of the plasma display in a way of being fixedly supported, hence to form the plasma display 50. In the plasma display 50 thus designed in modules, the analog interface 51 and the PDP module 1 can be manufactured separately from the other components.

### FOURTH EMBODIMENT

Hereinafter, a fourth embodiment of the invention will be described. The fourth embodiment has the form in which when a memory access circuit writes test data, it writes the test data with a clock of frequency much slower than that of a reference clock (the frequency used in writing the actual data).

The respective memory access circuits of the above first embodiment to third embodiment write and read the test data with the same reference clock frequency when performing the writing/reading on a memory. More specifically, the memory access circuit writes the test data into a memory in synchronization with a reference clock of predetermined frequency, reads the written test data in synchronization with the reference clock of the same frequency, and compares the written test data with the read test data.

A memory access circuit according to the fourth embodiment is the same as the circuit shown as the block diagram in FIG. 2. The operation of the memory access circuit in the fourth embodiment is different from that of the first embodiment as follows. Specifically, the memory access circuit in the fourth embodiment writes the test data using a clock much slower than a reference clock. According to this, the writing test data can be properly written at a predetermined address. The test data is read out in synchronization with the reference clock used for reading out the actual data at a predetermined address and a timing of reading out the test data is adjusted by the clock delay adjusting circuit, thereby enabling it to adjust the data reading timing from a memory. Further, the address in an exclusive use for writing the test data may be provided in the memory. The memory access circuit adjusts the memory access timing with the test data written at the exclusive address. Only one execution of a writing operation of the test data, for example, at a power-on of the circuit, is enough because the exclusive address is provided in the memory. The test data written at the exclusive address is stored in the memory until power is broken. In the case of adjusting the reading timing of data by using such a memory as having this exclusive address, the test data is read out from the exclusive address in synchronization with a reference clock. The test data reading timing can be adjusted by the clock delay adjusting circuit, hence to adjust the data reading timing from a memory.

### FIFTH EMBODIMENT

Hereinafter, a fifth embodiment of the invention will be described. A memory access circuit of the fifth embodiment is the same as the circuit shown as the block diagram in FIG. 8. The operation of the memory access circuit in the fifth embodiment is different from that of the second embodiment in the following operation. Specifically, the fifth embodiment is of the form in the case where the memory access circuit reads the test data with a clock of frequency much slower than that of a reference clock. The memory access circuit in the fifth embodiment delays a reference clock of predetermined frequency, so to create a plurality of delay clocks. The memory access circuit writes the test data into a memory in synchronization with each of the delay clocks. When reading the written test data, the memory access circuit reads it from a memory with a clock much slower than the reference clock. Thus, it is possible to accurately know whether the writing test data has been properly written at a predetermined address.

### SIXTH EMBODIMENT

Hereinafter, a sixth embodiment of the invention will be described. A memory access circuit in the sixth embodiment is the same as the circuit shown as the block diagram in FIG. 11. The operation of the memory access circuit in the sixth embodiment is different from that of the third embodiment in the following points. Specifically, the sixth embodiment is of the form in the case where the test data is written with a clock of frequency much slower than that of a reference clock when using the DDR SDRAM 21 as a memory. Similarly to the fourth embodiment, in the case of writing the test data, a clock much slower than the reference clock is used in order to do so. This enables it to write the writing test data properly at a predetermined address. Further, an address for the exclusive use in writing the test data may be provided in the DDR SDRAM 21.

The test data is read out from a predetermined address in synchronization with the reference clock used for reading out the actual data and the reading timing of the test data or the output data-strobe signal is adjusted by the first delay adjusting circuit. Thus, the data reading timing from the DDR SDRAM 21 can be adjusted. A delay amount adjusted here is set in the first delay adjusting circuit, to read the actual data, and therefore, the data can be read at a proper memory access timing.

### SEVENTH EMBODIMENT

Hereinafter, a seventh embodiment of the invention will be described. A memory access circuit in the seventh embodiment is the same as the circuit shown as the block diagram in FIG. 11. The operation of the memory access circuit in the seventh embodiment is different from that of the third embodiment in the following operation. More specifically, the seventh embodiment is of the form in the case where the test data is read out with a clock of frequency much slower than that of a reference clock when using the DDR SDRAM 21 as a memory. In the seventh embodiment, when writing the test data into the DDR SDRAM 21, it writes the test data in synchronization with the reference clock of the frequency used for writing the actual data. Here, the second delay adjusting circuit delays an input data-strobe signal synchronous with the test data, so to create a plurality of delay input data-strobe signals. The test data is written into the DDR SDRAM 21 in synchronization with the respective delay input data-strobe signals. When reading out the written test data, it reads the test data with a clock of frequency much slower than that of a reference clock. The test data written into the DDR SDRAM 21 at a predetermined address is compared with the test data written in synchronization with the delay input data-strobe signal. Thus, it is possible to adjust the timing properly when writing data into the DDR SDRAM 21. A delay amount adjusted here is set in the second delay adjusting circuit, so to write the actual data, thereby enabling it to write the data at a proper memory access timing.

According to the adjustment of a memory access timing in the sixth embodiment and the seventh embodiment, the output data-strobe signal and the input data-strobe signal can be separately adjusted and therefore, more accurate adjustment of a memory access timing can be performed. In this case, it is not necessary to perform a test in combination of delay output data-strobe signals and delay input data-strobe signals in a matrix shape, and therefore, adjustment of a memory access timing can be completed for a short time.

A semiconductor integrated circuit having the memory access circuit in the above-mentioned embodiments requires a frame memory of large capacity and it can provide a stable operation effectively when it is mounted on a system used under such an operational environment that the temperature varies from −10° C. to +80° C. A semiconductor integrated circuit having the memory access circuit described in each of the embodiments of the invention is very effective when it is mounted on a system having variation in initial setting of power voltage of LSI. Therefore, the memory access circuit of each of the embodiments is effective in operating stably when it is mounted on a large-sized display represented by a plasma display. The above-mentioned embodiments may be executed in combination unless there arises contradiction.

1. A memory access circuit comprising:
a memory;
a clock generator for generating a reference clock signal;
a clock delay adjusting circuit for delaying the reference clock signal to create a plurality of delay clock signals of various delay values;
a test data generator for generating test data; and
a memory access test controller for supplying a memory test start signal in reply to an external synchronizing signal, wherein
the test data generator generates the test data in reply to the memory test start signal, writes the test data into the memory in synchronization with the reference clock, and supplies write data corresponding to the test data in synchronization with the reference clock, and
the memory access test controller reads the test data from the memory in synchronization with the delay clock signal, compares the read test data with the write data, and adjusts a memory access timing according to a result of the comparison.

2. The memory access circuit according to claim 1, further comprising:
a data reading circuit for reading the test data written into the memory in synchronization with each of the delay clock signals; and
a comparator for comparing the read test data with the write data, wherein
the data reading circuit reads the test data in synchronization with each of the delay clock signals,
the comparator compares each of the read test data with the write data and notifies the memory access test controller of the comparison result, and
the memory access test controller adjusts the memory access timing according to the comparison result.

3. The memory access circuit according to claim 2, further comprising a data delay adjusting circuit, wherein the test data generator generates the test data in reply to the memory test start signal and supplies the test data to the data delay adjusting circuit in synchronization with the reference clock, and
the data delay adjusting circuit adjusts a writing timing into the memory based on the comparison between the test data and the read test data.

4. A memory access circuit comprising:
a memory for specifying an input timing of data according to an input data-strobe signal and specifying an output timing of data according to an output data-strobe signal;
a first delay adjusting circuit for delaying the output data-strobe signal to create a plurality of delay output data-strobe signals of various delay values;
a test data generator for generating test data;
a memory access controller for creating address data and the input data-strobe signal; and
a memory access test controller for supplying a memory test start signal in reply to an external synchronizing signal, wherein
the test data generator generates the test data in reply to the memory test start signal and enters the same data into the memory,
the memory access controller enters the input data-strobe signal into the memory in synchronization with the test data, and
the memory access test controller reads the test data from the memory in synchronization with the delay output data-strobe signal, compares the test data generated in the test data generator with the read data, and adjusts a memory access timing according to a result of the comparison.

5. The memory access circuit according to claim 4, wherein the memory access timing is adjusted by comparing the read test data with the test data generated by the test data generator according to the delay output data-strobe signals of various delay values generated by the first delay adjusting circuit and by selecting the delay output data-strobe signal in case where the comparison results in agreement.

6. The memory access circuit according to claim 4, further comprising a second delay adjusting circuit for delaying the input data-strobe signal to create a delay input data-strobe signal, wherein
the second delay adjusting circuit creates a plurality of delay input data-strobe signals of various delay values and enters the same signals into the memory, and
the memory access test controller reads the test data from the memory in synchronization with the delay output data-strobe, compares the test data generated by the test data generator with the read test data, and adjusts the memory access timing according to a result of the comparison.

7. The memory access circuit according to claim 6, wherein the memory access timing is adjusted by comparing the read test data with the test data generated by the test data generator according to each combination of the delay output data-strobe signals of various delay values generated by the first delay adjusting circuit and the delay input data-strobe signals of various delay values generated by the second delay adjusting circuit and by selecting the combination of the delay output data-strobe signal and the delay input data-strobe signal in case where the comparison results in agreement.

8. The memory access circuit according to claim 4, wherein a memory access to actual data is performed at the adjusted memory access timing.

9. The memory access circuit according to claim 1, wherein the memory access test controller adjusts the memory access timing between a front porch of the external synchronizing signal and a back porch of the external synchronizing signal.

10. The memory access circuit according to claim 1, wherein
the external synchronizing signal includes a first signal and a second signal and has a blanking period including no data signal between the first signal and the second signal, and
the memory access test controller adjusts the memory access timing during the blanking period.

11. A display comprising:
a memory access circuit; and
a display unit for displaying an external display signal, wherein
the memory access circuit includes:
a memory;
a clock generator for generating a reference clock signal;
a clock delay adjusting circuit for delaying the reference clock signal to create a plurality of delay clock signals of various delay values;
a test data generator for generating test data; and
a memory access test controller for supplying a memory test start signal in reply to an external synchronizing signal,
wherein the test data generator generates the test data in reply to the memory test start signal, writes the test data into the memory in synchronization with the reference clock, and supplies write data corresponding to the test data in synchronization with the reference clock,
the memory access test controller reads the test data from the memory in synchronization with the delay clock signal, compares the read test data with the write data, and adjusts a memory access timing according to a result of the comparison, and
the memory access circuit adjusts the memory access timing during a period of horizontal synchronizing signal or vertical synchronizing signal of the external display signal, or during a predetermined period after predetermined elapse of time since the horizontal synchronizing signal or the vertical synchronizing signal.

12. The display according to claim 11, wherein the memory access circuit adjusts the memory access timing in every predetermined number of horizontal synchronizing signals or vertical synchronizing signals, or in every predetermined time.

13. An operation method of a memory access circuit, comprising the steps of:
creating a reference clock;
delaying the reference clock signal to create a plurality of delay clocks of various delay values;
supplying a memory test start signal in reply to an external synchronizing signal;
creating the test data in reply to the memory test start signal;
writing the test data into the memory in synchronization with the reference clock;
reading the written test data from the memory in synchronization with the delay clock;
comparing the test data with the read data;
selecting the delay clock according to a result of the comparison;
writing an image signal into the memory; and
reading the image signal from the memory in synchronization with the selected delay clock.

14. The operation method of a memory access circuit according to claim 13, further comprising the step of adjusting the memory access timing between a front porch of the external synchronizing signal and a back porch of the external synchronizing signal.

15. The operation method of a memory access circuit according to claim 13, further comprising the step of adjusting the memory access timing during a blanking period including no data signal between first and second signals, said first and second signals being included in the external synchronizing signal.

16. The operation method of a memory access circuit according to claim 13, wherein the external synchronizing signal is a vertical synchronizing signal or a horizontal synchronizing signal.

17. An operation method of a memory access circuit, comprising the steps of:
creating a reference clock;
supplying a memory test start signal in reply to an external synchronizing signal;
generating the test data in reply to the memory test start signal;
delaying the test data to create a plurality of delay test data of various delay values;
writing the delay test data into a memory in synchronization with the reference clock;
reading the written data from the memory;
comparing the test data with the read data; and
selecting the delay value according to a result of the comparison, wherein an image signal is written with the selected delay value.

18. The operation method of a memory access circuit according to claim 17, further comprising the step of adjusting the memory access timing between a front porch of the external synchronizing signal and a back porch of the external synchronizing signal.

19. The operation method of a memory access circuit according to claim 17, further comprising the step of adjusting the memory access timing during a blanking period including no data signal between first and second signals, said first and second signals being included in the external synchronizing signal.

20. The operation method of a memory access circuit according to claim 17, wherein the external synchronizing signal is a vertical synchronizing signal or a horizontal synchronizing signal.

21. An operation method of a memory access circuit for a memory which specifies an input timing of input data according to an input data-strobe signal and specifies an output timing of output data according to an output data-strobe signal, comprising the steps of:
supplying a memory test start signal in reply to an external synchronizing signal;
creating test data in reply to the memory test start signal and entering the same data into the memory;
entering the input data-strobe signal into the memory in synchronization with the test data;
delaying the output data-strobe signal to create a plurality of delay output data-strobe signals of various delay values;
reading the data entered into the memory in synchronization with the delay output data-strobe signal;
comparing the test data with the read data; and
selecting the delay output data-strobe signal according to a result of the comparison, wherein a data signal is entered into the memory and the data signal is read from the memory in synchronization with the selected delay output data-strobe signal.

22. The operation method of a memory access circuit according to claim 21, further comprising the step of adjusting the memory access timing between a front porch of the external synchronizing signal and a back porch of the external synchronizing signal.

23. The operation method of a memory access circuit according to claim 21, further comprising the step of adjusting the memory access timing during a blanking period including no data signal between first and second signals, said first and second signals being included in the external synchronizing signal.

24. The operation method of a memory access circuit according to claim 21, wherein the external synchronizing signal is a vertical synchronizing signal or a horizontal synchronizing signal.

25. An operation method of a memory access circuit for a memory which specifies an input timing of input data according to an input data-strobe signal and specifies an output timing of output data according to an output data-strobe signal, comprising the steps of:
supplying a memory test start signal in reply to an external synchronizing signal;
creating test data in reply to the memory test start signal and entering the same data into the memory;
entering the input data-strobe signal into the memory in synchronization with the test data;
delaying the input data-strobe signal to create a plurality of delay input data-strobe signals of various delay values and entering the same signals into the memory;
reading the data entered into the memory in synchronization with the delay output data-strobe signal;
comparing the test data with the read data; and
adjusting the memory access timing according to a result of the comparison.

26. The operation method of a memory access circuit according to claim 25, further comprising the step of adjusting the memory access timing between a front porch of the external synchronizing signal and a back porch of the external synchronizing signal.

27. The operation method of a memory access circuit according to claim 26, further comprising the step of adjusting the memory access timing during a blanking period including no data signal between first and second signals, said first and second signals being included in the external synchronizing signal.

28. The operation method of a memory access circuit according to claim 26, wherein the external synchronizing signal is a vertical synchronizing signal or a horizontal synchronizing signal.

29. A memory access circuit comprising:
a memory; and
a clock delay adjusting circuit for delaying a reference clock to create a delay clock for use in reading actual data from the memory or a data delay adjusting circuit for delaying the actual data supplied in synchronization with the reference clock and entering the same data into the memory, wherein
a blanking period receiving no data signal is detected in every predetermined time, or a synchronizing signal for specifying the blanking period is received in every predetermined time;
a plurality of different delay amounts are set during the blanking period in the clock delay adjusting circuit or in the data delay adjusting circuit;
test data is read from the memory with the delay amounts, or the test data is written into the memory;
the original test data is compared with the read test data or the written test data; and the delay amount of the clock delay adjusting circuit when reading the actual data from the memory or the delay amount of the data delay adjusting circuit when writing the actual data into the memory is adjusted according to a result of the comparison.

30. The memory access circuit according to claim 29, wherein address data for specifying an address of the memory where the actual data is stored is entered into the memory in synchronization with the reference clock and the actual data is read from the memory in synchronization with the delay clock,
the address data for specifying an address of the memory where the original test data is stored, is entered into the memory in synchronization with the reference clock and the test data is read from the memory in synchronization with the delay clocks having various delay amounts, and
the original test data is compared with the read test data and the delay amount of the delay clock when reading the actual data from the memory is adjusted according to a result of the comparison.

31. The memory access circuit according to claim 29, wherein
the actual data to be written into the memory is entered into the delay adjusting circuit in synchronization with the reference clock, the address data for specifying a write address of the memory is entered into the memory in synchronization with the reference clock, and delay actual data delayed in the data delay adjusting circuit is entered into the memory,
test data to be written into the memory is entered into the data delay adjusting circuit in synchronization with the reference clock and the address data for specifying the write address of the memory is entered into the memory in synchronization with the reference clock,
the data delay adjusting circuit enters the delay test data having various delay amounts into the memory, compares the delay test data entered into the memory with the data written into the write address of the memory, and adjusts the delay amount of the data delay circuit according to a result of the comparison.

32. A memory access circuit comprising:
a memory for specifying an input timing of data according to an input data-strobe signal or specifying an output timing of data according to an output data-strobe signal, and
a first delay adjusting circuit for delaying the output data-strobe signal to create a delay output data-strobe signal or a second delay adjusting circuit for delaying an input data-strobe signal supplied in synchronization with actual data supplied in synchronization with a reference clock to create a delay input data-strobe signal, wherein
the address data for specifying an address of the memory where the actual data is stored is entered into the memory in synchronization with a reference clock, the actual data is read from the memory in synchronization with the delay output data-strobe signal or the original data is entered into the memory in synchronization with the reference clock, and the delay input data-strobe signal delayed by the second delay adjusting circuit is entered into the memory.

33. The memory access circuit according to claim 32, wherein
a blanking period receiving no data signal is detected in every predetermined time or a synchronizing signal for specifying the blanking period is received in every predetermined time,
the first delay adjusting circuit creates a plurality of delay output data-strobe signals of various delay amounts during the blanking period to enter the address data for specifying an address of the memory where the test data is stored, into the memory in synchronization with the reference clock, and
the test data is read from the memory in synchronization with the delay output data-strobe signals, the test data stored into the memory is compared with the read test data, a delay amount of the first data delay adjusting circuit when reading the actual data from the memory is adjusted according to a result of the comparison.

34. The memory access circuit according to claim 32, wherein the actual data and the address data for specifying the address of the memory where the actual data is written are entered into the memory in synchronization with the reference clock.

35. The memory access circuit according to claim 32, in which
the blanking period receiving no data signal is detected in every predetermined time or the synchronizing signal for specifying the blanking period is received in every predetermined time,
the second delay adjusting circuit creates a plurality of delay input data-strobe signals of various delay amounts during the blanking period to enter the test data into the memory in synchronization with the reference clock, and
the delay input data-strobe signals are entered into the memory, the test data entered into the memory is compared with the test data written into the address of the memory, and a delay amount of the second delay adjusting circuit when writing the actual data into the memory is adjusted according to a result of the comparison.

36. The memory access circuit according to claim 26, in which the test data and the address data for specifying the address of the memory where the test data is written are entered into the memory in synchronization with the reference clock.

37. A display comprising a memory access circuit and a display unit, the memory access circuit including:
a memory; and
a clock delay adjusting circuit for delaying a reference clock to create a delay clock for use in reading actual data from the memory or a data delay adjusting circuit for delaying the actual data supplied in synchronization with the reference clock to enter the actual data into the memory, wherein
the memory access circuit detects a blanking period receiving no data signal in every predetermined time, or receives a synchronizing signal for specifying the blanking period in every predetermined time, sets a plurality of various delay amounts during the blanking period in the clock delay adjusting circuit or the data delay adjusting circuit, reads the test data from the memory or writes the test data into the memory with the delay amounts, compares the original test data with the read test data or the written test data, and adjusts a delay amount of the clock delay adjusting circuit when reading the actual data from the memory or a delay amount of the data delay adjusting circuit when writing the actual data into the memory according to a result of the comparison, and
the display unit displays the actual data.
